(19) United States
(12) Patent Application Publication
(10) Pub. No.: US 2003/0063645 A1
(43) Pub. Date: Apr. 3, 2003

(54) Semiconductor laser device and method for suppressing fabry perot oscillations

(75) Inventors: Junji Yoshida, Tokyo (JP); Naoki Tsukiji, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: THE FURUKAWA ELECTRIC CO., LTD., Tokyo (JP)

(21) Appl. No.: 10/252,556

(22) Filed: Sep. 24, 2002

(30) Foreign Application Priority Data
Sep. 28, 2001 (JP) 2001-301074

(51) Int. Cl. H01L 33/00; H01S 5/00; H01S 3/08

(52) U.S. Cl. 372/49; 257/98; 372/50; 372/92; 372/98; 372/99; 372/102

(57) ABSTRACT

An integrated diffraction grating semiconductor laser device having an active layer configured to radiate light, a light reflecting facet positioned on a first side of the active layer, and a light emitting facet positioned on a second side of the active layer thereby forming a resonator between the light reflecting facet and the light emitting facet. A diffraction grating is positioned within the resonator along the length of the active layer. At least one of the light reflecting and light emitting facets is horizontally offset by an offset angle with respect to the light emitting direction of the laser device so as to reduce the reflectivity of the facet and suppress Fabry-Perot oscillations.

### CROSS REFERENCE TO RELATED APPLICATIONS

This application includes subject matter related to U.S. patent application Ser. Nos. 09/832,885 filed on Apr. 12, 2001, 09/983,175 filed on Oct. 23,2001, and 09/983,249 filed on Oct. 23, 2001. The entire contents of each of these applications is incorporated herein by reference.

### FIELD OF THE INVENTION

The present invention relates generally to semiconductor laser device, and in particular to a semiconductor laser device used as a pumping source for an optical amplifier.

### BACKGROUND OF THE INVENTION

With the proliferation of multimedia features on the Internet in the recent years, there has arisen a demand for larger data transmission capacity for optical communication systems. Conventional optical communication systems transmitted data on a single optical fiber at a single wavelength of 1310 nm or 1550 nm, which have reduced light absorption properties for optical fibers. However, in order to increase the data transmission capacity of such single fiber systems, it was necessary to increase the number of optical fibers laid on a transmission route, which resulted in an undesirable increase in costs.

In view of this, there has recently been developed wavelength division multiplexing (WDM) optical communications systems such as the dense wavelength division multiplexing (DWDM) system wherein a plurality of optical signals of different wavelengths can be transmitted simultaneously through a single optical fiber. These systems generally use an Erbium Doped Fiber Amplifier (EDFA) to amplify the data light signals as required for long transmission distances. WDM systems using EDFA initially operated in the 1550 nm band which is the operating band of the Erbium Doped Fiber Amplifier and the band at which gain flattening can be easily achieved. While use of WDM communication systems using the EDFA has recently expanded to the small gain coefficient band of 1580 nm, there has nevertheless been an increasing interest in an optical amplifier that operates outside the EDFA band because the low loss band of an optical fiber is wider than a band that can be amplified by the EDFA; a Raman amplifier is one such optical amplifier.

In a Raman amplifier system, a strong pumping light beam is pumped into an optical transmission line carrying an optical data signal. As is known to one of ordinary skill in the art, a Raman scattering effect causes a gain for optical signals having a frequency approximately 13 THz smaller than the frequency of the pumping beam (the pumping wavelength is approximately 100 nm shorter than the signal wavelength, which is typically in the vicinity of 1500 nm). Where the data signal on the optical transmission line has this longer wavelength, the data signal is amplified. Thus, unlike an EDFA where a gain wavelength band is determined by the energy level of an Erbium ion, a Raman amplifier has a gain wavelength band that is determined by a wavelength of the pumping beam and, therefore, can amplify an arbitrary wavelength band by selecting a pumping light wavelength. Consequently, light signals within the entire low loss band of an optical fiber can be amplified with the WDM communication system using the Raman amplifier and the number of channels of signal light beams can be increased as compared with the communication system using the EDFA.

For the EDFA and Raman amplifiers, it is desirable to have a high output laser device as a pumping source. This is particularly important for the Raman amplifier, which amplifies signals over a wide wavelength band, but has relatively small gain. Such high output is generally provided by a pumping source having multiple longitudinal modes of operation. The Furukawa Electric Co., Ltd. has recently developed an integrated diffraction grating device that provides a high output multiple mode laser beam suitable for use as a pumping source in a Raman amplification system. An integrated diffraction grating device, as opposed to a fiber brag grating device, includes the diffraction grating formed within the semiconductor laser device itself. Examples of multiple mode oscillation integrated diffraction grating devices are disclosed in U.S. patent application Ser. Nos. 09/832,885 filed on Apr. 12, 2001, 09/983,175 filed on Oct. 23, 2001, and 09/983,249 filed on Oct. 23, 2001, assigned to The Furukawa Electric Co., Ltd. and the entire contents of these applications are incorporated herein by reference.

As disclosed in the 09/832,885, 09/983,175, and 09/983,249 patent applications, a multiple longitudinal mode laser device having an integrated diffraction grating preferably has a low reflectivity at the light emitting facet of the laser device. As recognized by the present inventors, this low reflectivity of the light emitting facet of the laser device suppresses the Fabry-Perot oscillation of the device, thereby eliminating kinks in the current to light output (I-L) curve of the device and enhancing high output power operation. Such a low reflectivity is generally provided by an antireflective coating on the cleaved facet of the laser device. However, the present inventors have recognized that such antireflective coatings are difficult to produce due to limitations in thickness control of the coating process. Moreover, the present inventors have recognized that antireflective coating techniques are limited for producing very low reflectivity over the wide wavelength.

### SUMMARY OF THE INVENTION

Accordingly, one object of the present invention is to provide a laser device and method for providing a light source suitable for use as a pumping light source in a Raman amplification system, but which overcomes the above described problems.

Another object of the present invention is to provide a laser device having suppressed Fabry-Perot oscillations.

Yet another object of the present invention is to provide a laser device having a laser facet with a low reflectivity.

According to a first aspect of the present invention, a semiconductor device and method for providing a light source suitable for use as a pumping light source in a Raman amplification system are provided. The device upon which the method is based includes an active layer configured to radiate light, a light reflecting facet positioned on a first side of the active layer, and a light emitting facet positioned on a second side of the active layer thereby forming a resonator between the light reflecting facet and the light emitting facet. A diffraction grating is positioned within the resonator along the length of the active layer. At least one of the light reflecting and light emitting facets is horizontally offset by an offset angle with respect to the light emitting direction of the laser device.

Either the light emitting facet or the light reflecting facet, or both the light emitting and light reflecting facets may be horizontally offset to suppress Fabry-Perot oscillations. The light emitting facet and the light reflecting facet may be horizontally offset by an offset angle of 2° or more with respect to the light emitting direction. The light emitting facet and the light reflecting facet are preferably horizontally offset such that an effective reflectivity Reff of the respective facet is less than 0.1%. Moreover, the light reflecting facet and/or the light emitting facet may include a reflectance coating.

According to another aspect of the invention, a semiconductor laser module, an optical amplifier, a Raman amplifier, or a wavelength division multiplexing system may be provided with a semiconductor laser device having an active layer configured to radiate light, a light reflecting facet positioned on a first side of the active layer, and a light emitting facet positioned on a second side of the active layer thereby forming a resonator between the light reflecting facet and the light emitting facet. A diffraction grating is positioned within the resonator along the length of the active layer. At least one of the light reflecting and light emitting facets is horizontally offset by an offset angle with respect to the light emitting direction of the laser device so as to reduce the reflectivity of the facet and suppress Fabry-Perot oscillations.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a perspective view of a semiconductor laser device according to a first embodiment of the present invention;

FIG. 2 is a vertical sectional view in the longitudinal direction of a semiconductor laser according to the first embodiment of the present invention;

FIG. 3 is a cross sectional view along the line A-A of the semiconductor laser device shown in FIG. 2;

FIGS. 4 and 5 are top cross sectional views of two different semiconductor devices illustrating the advantage of an offset light emitting facet in accordance with the present invention;

FIGS. 6-8 illustrate the process steps for forming a semiconductor laser device in accordance with the first embodiment of the present invention;

FIGS. 9A and 9B illustrate an alternative method of fabricating a semiconductor laser device in accordance with the first embodiment of the present invention;

FIG. 10 is a vertical sectional view in the longitudinal direction of a semiconductor laser device according to a variation of the first embodiment of the present invention;

FIG. 11 is a top cross sectional view of a semiconductor laser device in accordance with a second embodiment of the present invention;

FIG. 12 is a top cross sectional view of a semiconductor laser device in accordance with a third embodiment of the present invention;

FIG. 13A is top cross sectional view of a semiconductor laser having an reflecting facet 14 and output facet 15 each forming an off angle with respect to a light output direction of the laser device due to cleavage planes of the device;

FIG. 13B is top cross sectional view of a semiconductor laser having an reflecting facet 14 and output facet 15 each forming an off angle with respect to a light output direction of the laser device due to cleavage planes and etching of the device;

FIG. 14 is a graph showing the reflectivity of a laser facet as a function of the off angle of the facet;

FIG. 15 is a graph showing the relation between the off-angle of a facet and the FFP to get a desired reflectivity;

FIG. 16 is a vertical sectional view illustrating the configuration of a semiconductor laser module having a semiconductor laser device according to the present invention;

FIG. 17 is a block diagram illustrating a configuration of a Raman amplifier used in a WDM communication system in accordance with the present invention;

FIGS. 18 and 19 show a block diagram illustrating a configuration of the Raman amplifier used in a WDM communication system in a forward and bidirectional pumping method respectively, in accordance with the present invention;

FIG. 20 is a block diagram illustrating a configuration of a Raman amplifier in which polarization dependency gain is suppressed by depolarizing a pumping light beam output from a single semiconductor laser device using polarization maintaining fibers as a depolarizer, in accordance with an embodiment of the present invention;

FIGS. 21 and 22 show a block diagram illustrating a configuration of the Raman amplifier used in a WDM communication system in a forward and bidirectional pumping method respectively, in accordance with the present invention;

FIG. 23 is a block diagram illustrating a general configuration of the WDM communication system to which the Raman amplifier shown in any of FIGS. 17-22 is applied.

### DESCRIPTION OF THE PREFERRED EMBODIMENTS

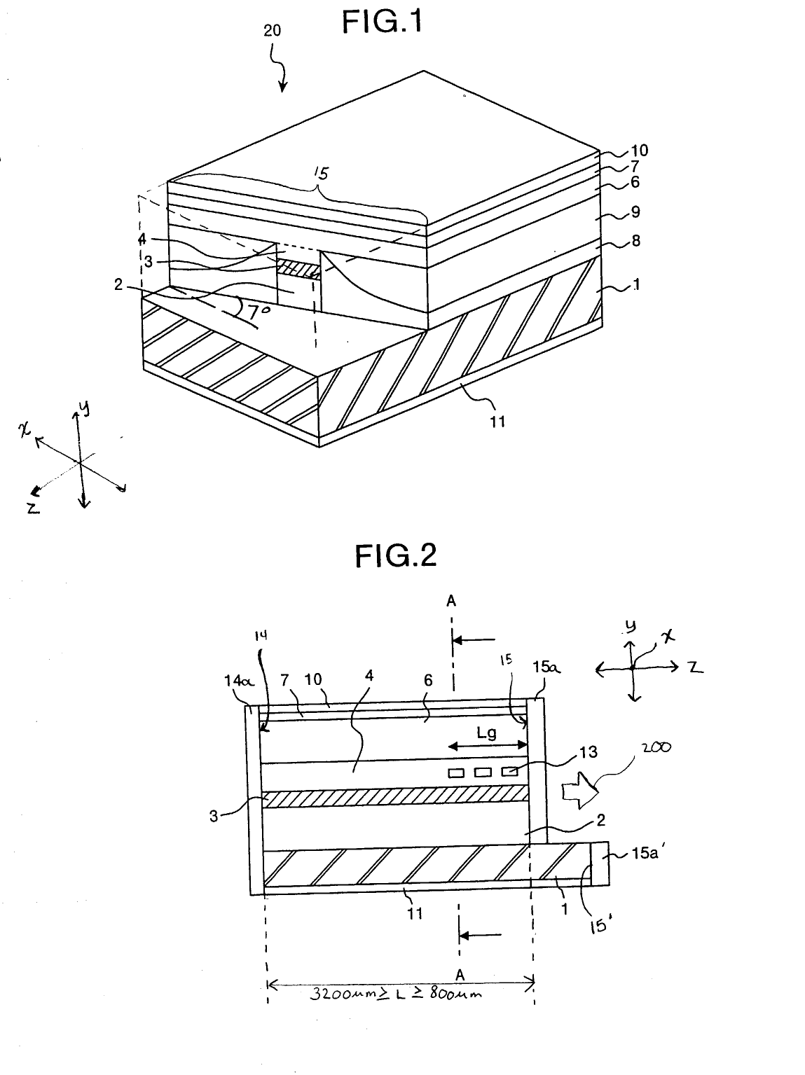

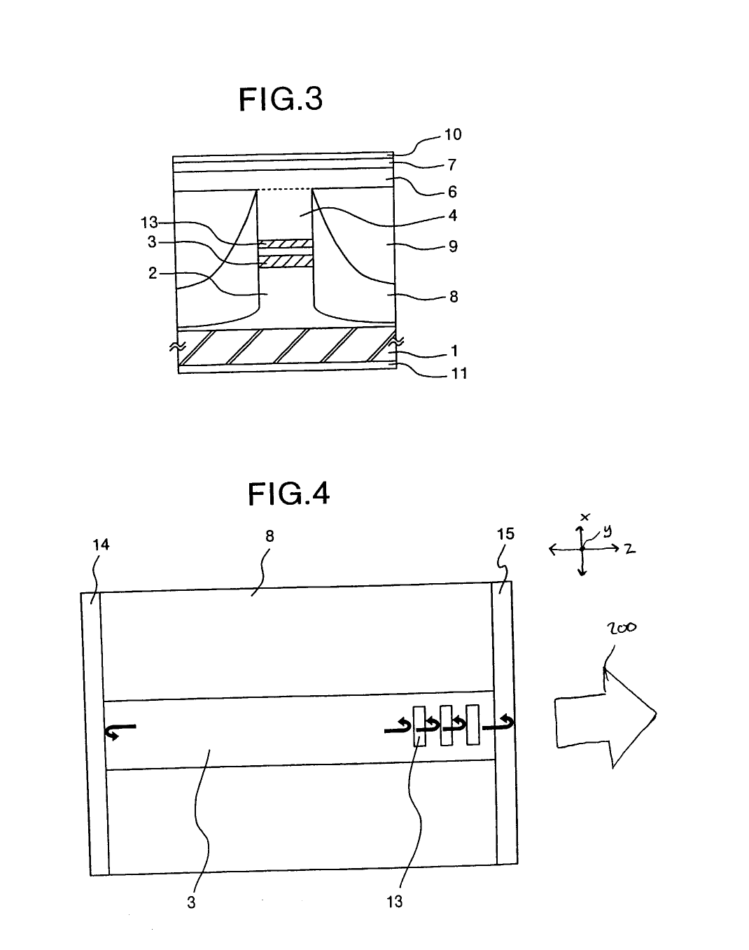

Referring now to the drawings wherein like elements are represented by the same reference designation throughout, and more particularly to FIGS. 1 through 3 thereof, there is shown a semiconductor laser device for providing a light source suitable for use as a pumping light source in a Raman amplification system, in accordance with a first embodiment of the present invention. FIG. 1 is a perspective view of the semiconductor device, FIG. 2 is a vertical sectional view in the longitudinal direction of the semiconductor laser device, and FIG. 3 is a cross sectional view of the semiconductor laser device, taken along the line A-A in FIG. 2.

The semiconductor laser device 20 of FIGS. 1 through 3 includes an n-InP substrate 1 having an n-InP buffer layer 2, an active layer 3, a p-InP spacer layer 4, a p-InP cladding layer 6, and a p-InGaAsP contact layer 7 sequentially stacked on a face of the substrate 1. Buffer layer 2 serves both as a buffer layer by the n-InP material and an under cladding layer, while the active layer 3 is a graded index separate confinement multiple quantum well (GRIN-SCH-MQW) structure. A diffraction grating 13 of a p-InGaAsP material is periodically formed within the p-InP spacer layer 4 along a portion of the entire length of active layer 3 to provide light reflecting properties in the laser cavity as will be further described below. Finally, a p-side electrode 10 is formed on the upper surface of InGaAsP cap layer 7, and an n-side electrode 11 is formed on the lower surface of n-InP substrate 1.

As seen in FIGS. 1 and 2, a plane 15 formed by the buffer layer 2, active layer 3, spacer layer 4, cladding layer 6, contact layer 7 and electrode 10, as well as blocking layers 8 and 9 is horizontally offset with respect to a plane perpendicular to the longitudinal direction of the semiconductor laser device 20 as shown in phantom in FIG. 1. Specifically, the front facet 15 is horizontally offset so as to form an angle of 7° with respect to the plane perpendicular to light output direction as will be further described below. The light output direction is depicted by arrow 200 throughout the drawings. As also seen in FIGS. 1 and 2, however, the substrate 1 at the light emitting end of the laser device 20 has a planar surface 15′ substantially perpendicular to the light emitting direction of the laser device 20. Moreover, in the embodiment of FIGS. 1-3, the entire surface at a light reflecting end of the laser device forms a plane 14 substantially perpendicular to the light emitting direction of the laser device 20.

As also seen in FIG. 2, a reflective film 14a having high reflectivity of, for example, 80% or more, and preferably 98% or more is formed on the light reflecting end surface of the semiconductor laser device 20. Antireflection coating 15a having a low reflectivity of, for example, less than 5%, less than 1%, or less than 0.5%, and most preferably less than 0.1% is formed on a light irradiating end surface opposing the light reflecting end surface of semiconductor laser device 20. It is also noted that the present invention is useful for laser devices having an uncoated light emitting facet with relatively high reflectivity of less than 30% or less than 10%, for example. The reflective film 14a and the antireflection coating 15a form a light resonator within the active region 3 of the semiconductor laser device 20. However, the offset facet 15 greatly decreases the amount of light reflected from the light emitting facet and returning to the laser cavity. According to the present invention, the grating 13 provides reflectivity characteristics sufficient to sustain oscillations in the laser device and provide a laser output. Specifically, a light beam generated inside the GRIN-SCH-MQW active layer 3 of the light resonator is oscillated between the reflective film 14a and the combination of the grating 13 and light emitting facet, and irradiated as an output laser beam via the antireflection coating 15a. In this way, a specific wavelength spectrum is selected by the diffraction grating 13 as the laser output.

The laser device 20 of FIGS. 1-3 is constructed so as to provide multiple longitudinal mode oscillation of the laser device. Thus, as seen in FIG. 2, the resonator length L is preferably from 800-3200 μm as described in U.S. patent application Ser. No. 09/832,885, which is incorporated herein by reference. In the embodiment of FIGS. 1 through 3, the diffraction grating 13 has a length Lg of approximately 50 μm, a film grating thickness of 20 nm, a grating pitch of 220 nm, and selects a laser beam having a central wavelength of 1480 nm to be emitted by the semiconductor laser device 20. Moreover, as best seen in FIG. 3, the p-InP spacer layer 4 having the diffraction grating 13, the GRIN-SCH-MQW active layer 3, and the upper part of the n-InP buffer layer 2 are processed in a mesa stripe shape and the sides of the mesa stripe are buried by a p-InP blocking layer 8 and an n-InP blocking layer 9.

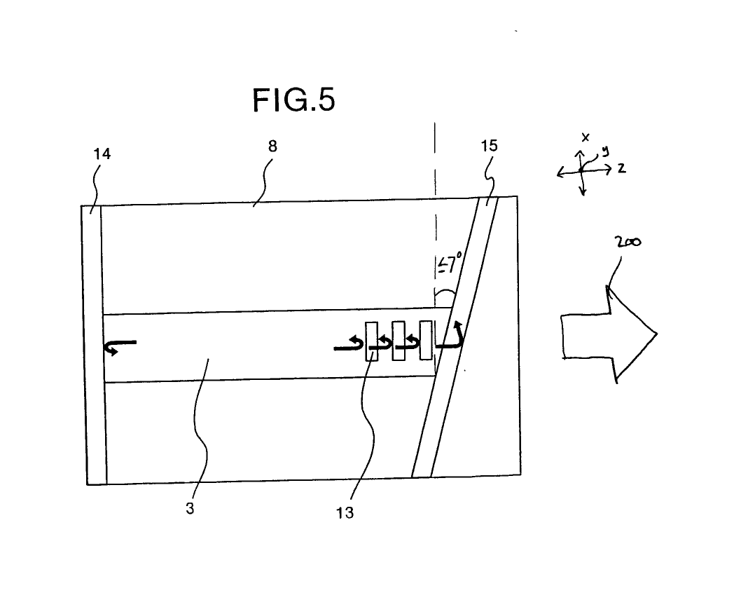

Thus, the semiconductor laser device of the first embodiment of the present invention provides a light reflecting facet that is substantially perpendicular to the light output direction and a light emitting facet forms an offset angle of 7° with respect to a plane perpendicular to the light output direction. Stated another way, the offset facet is horizontally offset by 7° from the phantom perpendicular plane shown in FIG. 1. The present inventors have discovered that a laser device having such a structure provides a stable and efficient output for multiple mode integrated diffraction grating devices. FIGS. 4 and 5 illustrate the advantages of the offset light emitting facet. FIG. 4 is top cross-sectional view of a semiconductor laser device having a front facet perpendicular to a light output direction. As seen in this figure, light (depicted by arrows) generated within the active layer 3 is reflected not only by the grating 13, but also by the radiation side reflection film 15. Such reflections from the radiation side reflection film cause Fabry-Perot oscillation modes that cause the oscillation state of the laser to become unstable. This reflection of the Fabry-Perot modes varies with changes in the injection current of the semiconductor laser device resulting in changes in the light output of the laser device. Thus, the current to light output (IL) curve for the device of FIG. 4 exhibits kinks representing undesirable non-linearity in the IL curve.

FIG. 5 is a top cross-sectional view of a semiconductor laser having a front facet 15a that forms an offset angle with respect to a light output direction. As seen in this figure, light reflected by the coated facet 15a is directed away from the active region 3. That is, the light reflected from the offset facet becomes incident on the blocking layer 8/active layer 3 boundary at such an angle that the light is not reflected or guided within the active layer 3, but rather penetrates the boundary to be attenuated by the block material. Therefore, it is possible to make the total effective reflectance of the coated facet 15a to be less than 0.1%, the light generated in the GRIN-SCH-MQW active layer 3 returns to the GRIN-SCH-MQW active layer 3 primarily by the diffraction grating 13. Accordingly, oscillation of the laser beam generated in the Fabry-Perot mode is suppressed, and the laser beam having a wavelength selected by the diffraction grating 13 is output efficiently. As a result, a kink in the injected current-laser output characteristic (IL characteristic) is eliminated, thereby enabling stable oscillation.

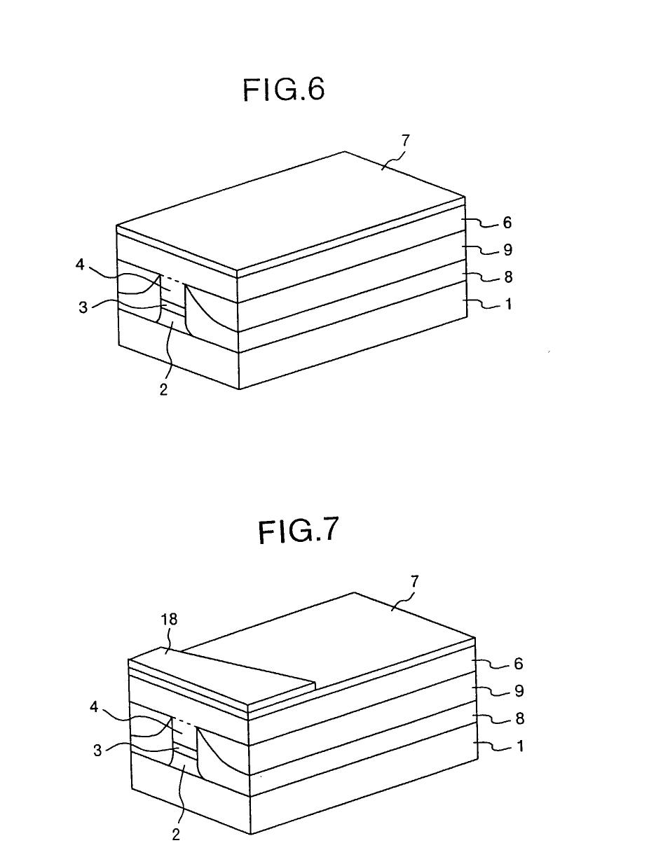

FIGS. 6-8 illustrate the process steps for forming a semiconductor laser device in accordance with the first embodiment of the present invention. As seen in FIG. 6, an n-InP clad layer 2, the GRIN-SCH-MQW active layer 3 and the P-InP spacer layer 4 including the diffraction grating 13 are sequentially laminated on the (100) plane of the n-InP substrate 1. A mesa shape is then formed by reactive ion etching (RIE) or wet etching. Thereafter, the p-InP blocking layer 8 and the n-InP blocking layer 9 are embedded in the etched regions, and the P-InP clad layer 6 and the P-InGaAsP contact layer 7 are formed on the upper surfaces of the P-InP spacer layer 4 and the n-InP blocking layer 9.

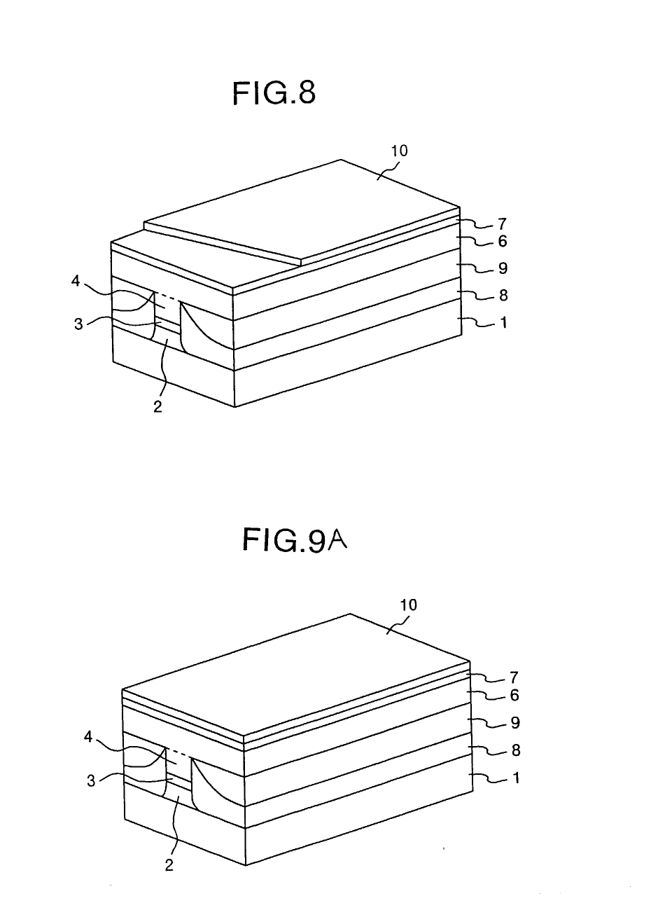

With the multilayer structure formed, a mask 18 is formed on an upper surface of the P-InGaAsP contact layer 7. The mask 18 is formed into a trapezoidal shape having one side that is horizontally offset with respect to the longitudinal direction of the GRIN-SCH-MQW active layer 3 (i.e. light output direction) as previously described. A positive electrode material is then deposited on the contact layer 7 where the mask 18 is absent, and the mask 18 is removed to form positive electrode 10 as shown in FIG. 8. In this regard, it is noted that the positive electrode 10 can be formed while avoiding the region corresponding to the radiation side reflection film 15a. Thereafter, a mask is formed on the upper surface of the positive electrode 10, and the P-InGaAsP contact layer 7, P-InP clad layer 6, P-InP spacer layer 4, active layer 3 and n-InP clad layer 2 are dry-etched to form the light radiation end surface. Thereafter, the negative electrode 11, is formed on the underside of substrate 1. Anti-reflection film 15a and reflection film 14a are then formed on the light emitting and reflecting facets respectively to form the semiconductor laser device 20 illustrated in FIG. 1.

FIGS. 9A and 9B describe an alternative method of fabricating a semiconductor laser device in accordance with the first embodiment of the present invention. In this alternative method, the region corresponding to the radiation side reflection film is removed after the positive electrode material is deposited. Thus, as seen in FIG. 9A an n-InP clad layer 2, the GRIN-SCH-MQW active layer 3 and the P-InP spacer layer 4 including the diffraction grating 13 are sequentially laminated on the (100) plane of the n-InP substrate 1. A mesa shape is then formed by reactive ion etching (RIE) or wet etching. Thereafter, the p-InP blocking layer 8 and the n-InP blocking layer 9 are embedded in the etched regions, and the P-InP clad layer 6, P-InGaAsP contact layer 7, and a p-side electrode 10 are sequentially formed on the upper surface of the P-InP spacer layer 4 and the n-InP blocking layer 9.

With the multilayer structure including the p-side electrode formed, a mask 19 is formed on the upper surface of the positive electrode 10. The mask 18 is formed into a trapezoidal shape having one side that is horizontally offset with respect to the longitudinal direction of the active layer 3 as shown in FIG. 9B. Then, a portion of the positive electrode 10 is removed using wet etching or dry etching, and the P-InGaAsP contact layer 7, P-InP clad layer 6, P-InP spacer layer 4, active layer 3 and n-InP clad layer 2 are dry-etched to form the light radiation end surface. Thereafter, a negative electrode 11 is formed on the underside of the substrate 1. Anti-reflection film and reflection film 14a are then formed on the light emitting and reflecting facets respectively to form the semiconductor laser device 20 shown in FIG. 1.

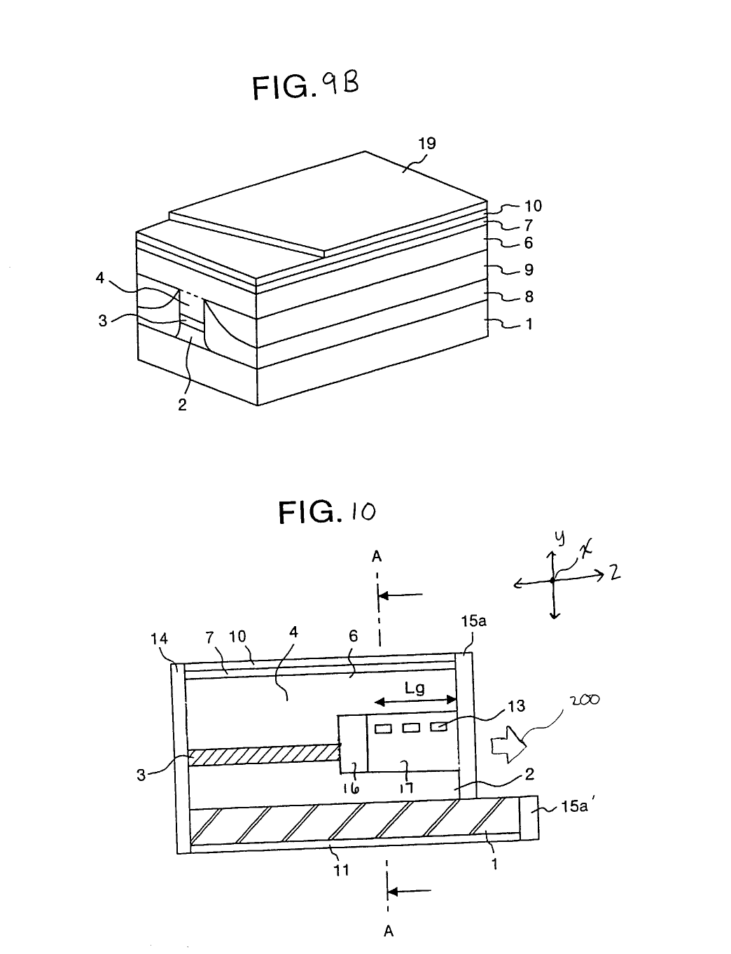

In the first embodiment described above, the semiconductor laser device is partially provided with the diffraction grating 13 along the GRIN-SCH-MQW active layer 3, but the invention is not limited to this structure. FIG. 10 shows a variation of the first embodiment of the present invention wherein the diffraction grating is formed along an optical waveguide of the semiconductor device. In the semiconductor laser device shown in FIG. 10, an optical waveguide layer 16 and an optical waveguide layer 17 including the diffraction grating are sequentially disposed in the longitudinal direction (laser beam emitting direction) from the GRIN-SCH-MQW active layer 3. As also seen in this figure, the front facet plane 15 and the film 15a formed thereon are horizontally offset with respect to the light output of the device as previously described. As a result, the reflectivity of the light emitting facet is reduced and unnecessary oscillation in the Fabry-Perot mode can be suppressed resulting in stable oscillation an increase in laser output efficiency.

The first embodiment illustrates the present invention with reference to the diffraction grating 13 provided in the vicinity of the offset light emitting facet plane. With this configuration, it is preferable that the diffraction grating length Lg and the resonator length L are set to satisfy the relationship Lg×(1300 μm/L)<300 μm. Moreover, the diffraction grating 13 is preferably constructed such that a value obtained by multiplying a coupling coefficient K of the diffraction grating by a diffraction grating length Lg is set to 0.3 or less. Examples of devices having a diffraction grating provided in the vicinity of the radiation side reflecting film may be found in U.S. patent application Ser. No. 09/983,249, which is incorporated herein by reference. It is to be understood, however, the present invention is not limited to devices having an offset plane diffraction grating provided in the vicinity of the offset light emitting facet.

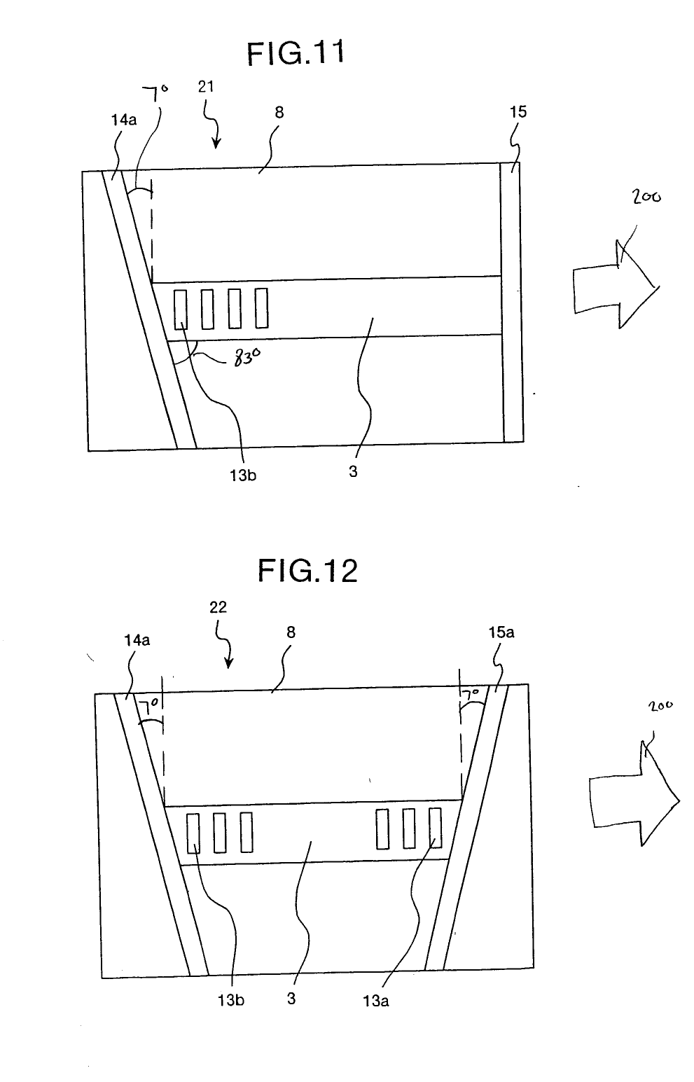

FIG. 11 is a top cross-sectional view in the longitudinal direction of a semiconductor laser device having a diffraction grating and offset facet on the light reflecting side of the device in accordance with a second embodiment of the present invention. As seen in this figure, the diffraction grating 13b is provided in the vicinity of the reflection film 14a. With such a configuration, it is preferable that the diffraction grating length Lgb and the resonator length L are set to satisfy the relationship Lg≧½L. Moreover, the diffraction grating 13b is preferably constructed such that a value obtained by multiplying a coupling coefficient κ of the diffraction grating by a diffraction grating length Lg is set to 1 or more, and selectively returns light to the radiation side by the reflectivity of 98% or higher. Examples of devices having a diffraction grating provided in the vicinity of the radiation side reflecting film may be found in U.S. patent application Ser. No. 09/983,175, which is incorporated herein by reference.

As also seen in FIG. 11, a plane 14a formed by the light reflecting end of the laser device is inclined with respect to the longitudinal direction of the semiconductor laser device along which light is emitted from the device as shown by the arrow 200. As with the first embodiment, the reflecting film 14a forms an angle of 83° (i.e., 7° offset angle) with respect to the light output direction, thereby significantly reducing the reflectance of plane 14a. However, by setting the product of the coupling coefficient K and the diffraction grating length Lgb of the diffraction grating 13b to an adequate value, as described above, almost all laser beams can be reflected by the diffraction grating 13b itself. Hence, even if the facet of the reflection coating 14 is inclined by the angle of the off angle, the laser beam can be sufficiently reflected.

FIG. 12 is a vertical sectional view in the longitudinal direction of a semiconductor laser device having a diffraction grating and inclined facet on both the light reflecting side and the light emitting side of the device in accordance with the third embodiment of the present invention. In this case, a bi-directional effect of the semiconductor laser device shown in FIG. 1 and the semiconductor laser device shown in FIGS. 11 can be obtained. As a result, while satisfying the wavelength selection option by means of the diffraction gratings 13a and 13b, the influence of the Fabry-Perot resonator due to the reflection coating 14a and the outgoing side reflection coating 15a can be reduced, and unnecessary oscillation in the Fabry-Perot mode can be suppressed. Furthermore, the emission wavelength can be selected by the diffraction gratings 13a and 13b, to stabilize the laser oscillation and increase the laser output efficiency, and a laser beam having a desired emission wavelength can be efficiently output.

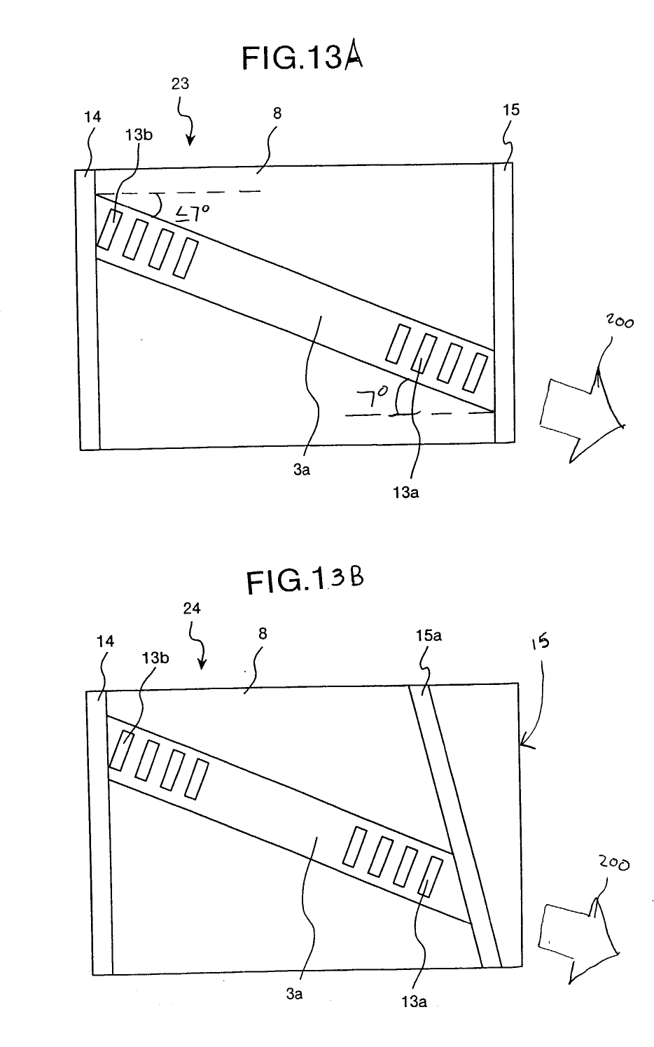

In each of the semiconductor laser devices described above, the offset of the light reflection and light emitting facets can be formed by an etching process as described with respect to FIGS. 6-8, and 9A and 9B. However, the offset angle of the light reflection or light emitting facets may be formed by a cleavage plane resulting from a process of separating the laser device from a semiconductor wafer. FIG. 13A is top cross sectional view of a semiconductor laser having an reflecting facet 14 and output facet 15 each forming an off angle with respect to a light output direction of the laser device due to cleavage planes of the device. As would be understood by one of ordinary skill in the art, the multilayer structure including the blocking layers 8, active region 3a and gratings 13a and 13b is first formed on the surface of a semiconductor wafer. In a preferred process, a plurality of such structures are formed on a single wafer and subsequently separated into discrete devices by a known cleaving process. Where the discrete laser device includes gratings 13a and 13b as shown in FIG. 13A, parallel cleave lines may be made at an offset angle with respect to the longitudinal direction of the active layer 3a, which defines the light output direction 200 of the laser device 23 as shown in FIG. 13A. Therefore, the formation of the light radiation end surface or the light reflection end surface by the etching can be omitted, and the same working effect as that of the semiconductor laser device 22 can be obtained. That is, the semiconductor laser device of FIG. 13 suppresses unnecessary oscillation in the Fabry-Perot mode resulting in stable oscillation and an increase in laser output efficiency.

FIG. 13B is top cross sectional view of a semiconductor laser having an reflecting facet 14 and output facet 15 each forming an off angle with respect to a light output direction of the laser device due to cleavage planes and etching of the device. As seen in this figure, cleave lines are made at an offset angle with respect to the longitudinal direction of the active layer 3a, as described with respect to FIG. 13A. In addition, however, the light emitting end of the device includes an etched area that defines the light emitting facet having an antireflective coating 15a thereon. Thus, the semiconductor laser device of FIG. 13B also suppresses unnecessary oscillation in the Fabry-Perot mode resulting in an increase in laser output efficiency.

In each of the above described embodiments of the invention, the off angle of the light emitting or light reflecting plane has been designated as 7°; however, the present invention is not limited thereto. For example, the present inventors have discovered that the benefits of the present invention may be realized when the angle of the off angle is 2° or larger. FIG. 14 is a calculation model illustrating the parameters used for calculating the effective reflectivity of the offset facet. The figure is a sketch of a laser waveguide terminated by a tilted mirror and is taken from the article “Reflection Loss of Laser Mode From Tilted End Mirror”, D. Marcuse, PP. 336-339, Journal of Lightwave technology Vol.7, No.2, February 1989, the entire contents of which is incorporated herein by reference.

Effective reflectivity is calculated from the power reflection coefficient Rg equation:

$${R}_{g} = {R}_{f} ( θ ) x \times {[ \frac{{WU}^{2} \{ [ {W}^{2} - {( βθ d )}^{2} ] \frac{sin ( 2 βθ d )}{2 βθ d} + W cos ( 2 βθ d ) \}}{( 1 + W ) [ {U}^{2} - {( βθ d )}^{2} ] [ {W}^{2} + {( βθ d )}^{2} ]} ]}^{2} \qquad ( 1 )$$

where

Rf is the Fresnel reflection coefficient of a plane wave that is reflected from the tilted dielectric interface between the laser crystal and air, and β is the propagation constant. The parameters U and W are, respectively, the normalized propagation constants of the wave in the slab core of the laser having a width 2 d

$$U = \sqrt{{n}_{1}^{2} {k}^{2} - {β}^{2} d} \qquad ( 2 )$$

and the normalized transfer decay parameter

$$W = \sqrt{{β}^{2} - {n}_{2}^{2} {k}^{2} d} \qquad ( 3 )$$

where

k is the free space wave number k=2II/λ (λ=free space wavelength).

A core of the width 2 d was estimated from following formula:

$$d = \frac{λ}{π \cdot ( tan ( \frac{{FFP}_{h}}{\sqrt{2 ln 2}} ) )} \qquad ( 4 )$$

where,

FFPh represents the horizontal angle of far field pattern. An FFPh of 13°-18° is required in order to achieve high power operation for the laser device.

Using these equations, λ was set to be 1480 nm, and n1 of 3.19 and n2 of 3.18 were used for the effective refractive index of an active region corresponding to a slab core and InP cladding, respectively. A propagation constant β of 13.56 was estimated from a laser structure by calculation. However, it is noted that parameters, such as effective refractive index and propagation constant, depend on the structure of the active layer and the oscillation wavelength.

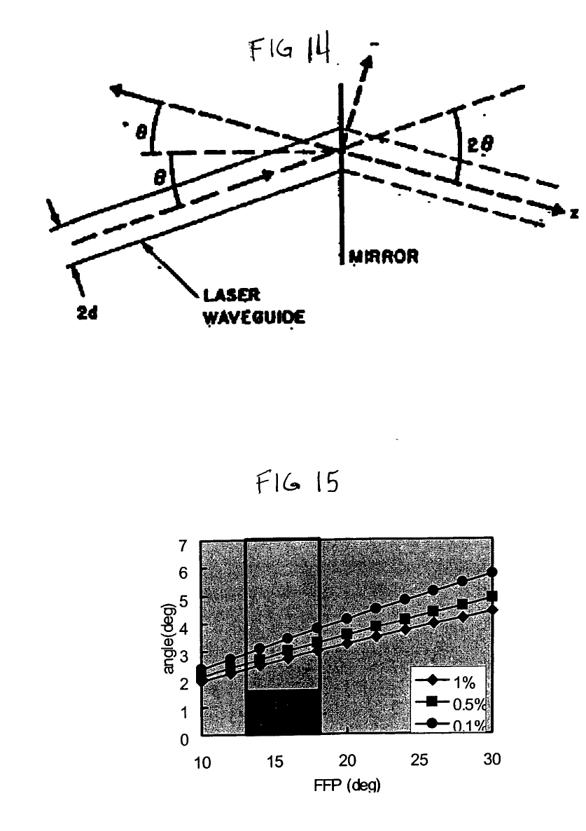

FIG. 15 is a graph showing the relation between the off-angle of a facet and the FFP to get a desired reflectivity. As noted above, the FFP is limited to the range of 13-18 degrees in order to provide high power operation of the laser device. Thus, as seen in FIG. 12, a range of off angles may be used to satisfy a particular reflectivity over the limited range of FFP. Specifically, a 1% reflectivity is obtained at the range of off-angle of 2.1-3 degrees and a 0.5% reflectivity is obtained at the range of off-angle of 2.4-3.3 degrees. The preferred reflectivity of 0.1% reflectivity is obtained at the range of off-angle of 3-3.8 degrees. Thus, an off-angle of no less than 2.1 degrees is required to get below 1% reflectivity. More preferably, no less than 3 degrees is required to get below 0.1%.

Finally, in each of the embodiments described above, the periodically spaced material of the diffraction grating 13 is equally spaced and has a constant period of the diffraction grating. However, it is to be understood that the grating material may have different spacings and periods of the diffraction gratings in order to achieve the desired multiple oscillation modes output from the laser device.

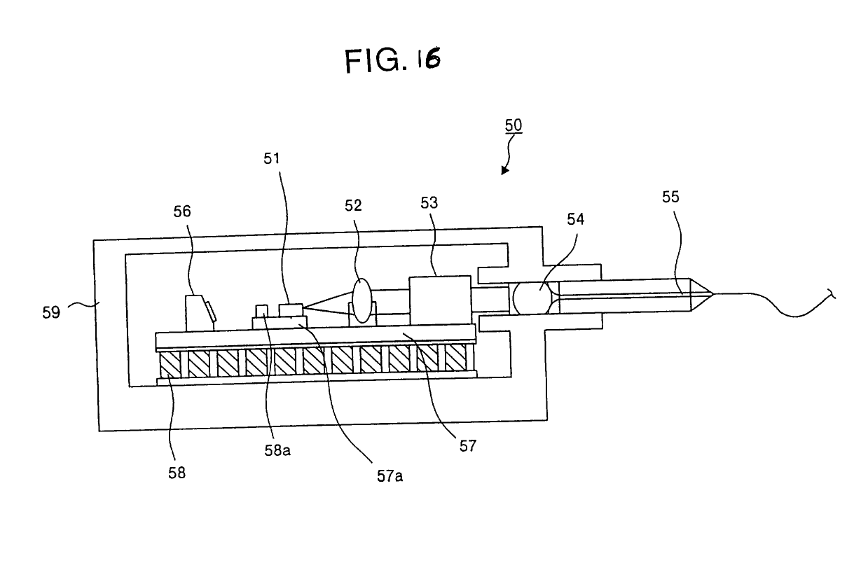

FIG. 16 is a vertical sectional view illustrating the configuration of a semiconductor laser module having a semiconductor laser device according to the present invention. The semiconductor laser module 50 includes a semiconductor laser device 51, a first lens 52, an internal isolator 53, a second lens 54 and an optical fiber 55. Semiconductor laser device 51 is an integrated grating device configured in accordance with any of the above-described semiconductor laser devices and a laser beam irradiated from the semiconductor laser device 51 is guided to optical fiber 55 via first lens 52, internal isolator 53, and second lens 54. The second lens 54 is provided on the optical axis of the laser beam and is optically coupled with the optical fiber 55.

The semiconductor laser device 51 is preferably provided in a junction down configuration in which the p-side electrode is joined to the heat sink 57a, which is mounted on the base 57. A back face monitor photo diode 56 is also disposed on a base 57 which functions as a heat sink and is attached to a temperature control device 58 mounted on the metal package 59 of the laser module 50. The back face monitor photo diode 56 acts as a current monitor to detect a light leakage from the reflection coating side of the semiconductor laser device 51.

The temperature control device 58 is a Peltier module. Although current (not shown) is given to the Peltier module 58 to perform cooling and heating by its polarity, the Peltier module 58 functions mainly as a cooler in order to prevent an oscillation wavelength shift by the increase of temperature of the semiconductor laser device 51. That is, if a laser beam has a longer wavelength compared with a desired wavelength, the Peltier element 58 cools the semiconductor laser device 51 and controls it at a low temperature, and if a laser beam has a shorter wavelength compared with a desired wavelength, the Peltier element 58 heats the semiconductor laser device 51 and controls it at a high temperature. By performing such a temperature control, the wavelength stability of the semiconductor laser device can improved. Alternatively, a thermistor 58a can be used to control the characteristics of the laser device. If the temperature of the laser device measured by a thermistor 58a located in the vicinity of the laser device 51 is higher, the Peltier module 58 cools the semiconductor laser device 51, and if the temperature is lower, the Peltier module 58 heats the semiconductor laser device 51. By performing such a temperature control, the wavelength and the output power intensity of the semiconductor laser device are stabilized.

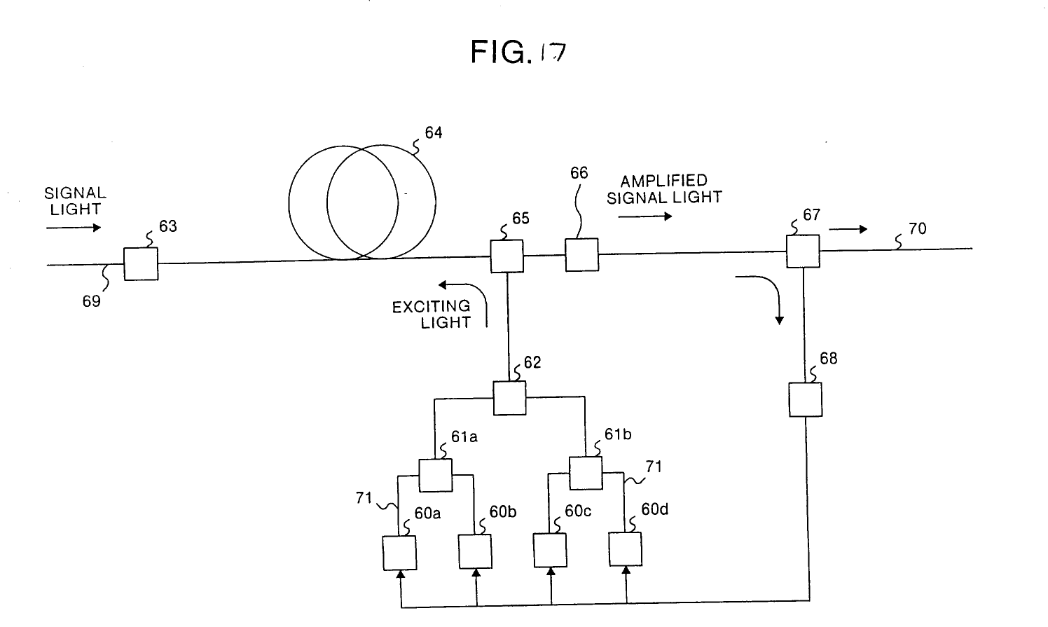

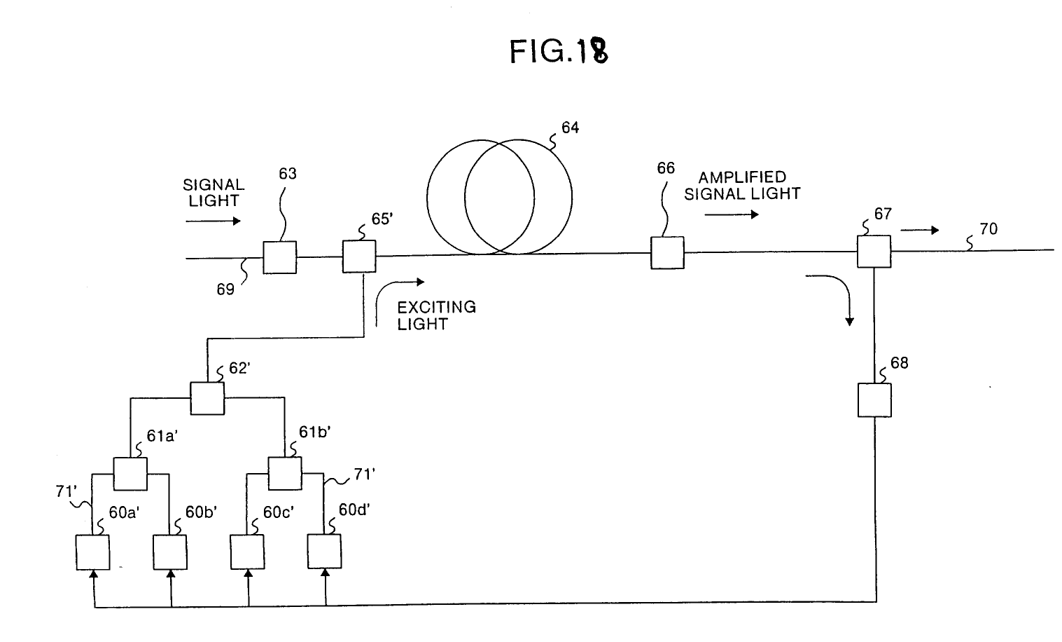

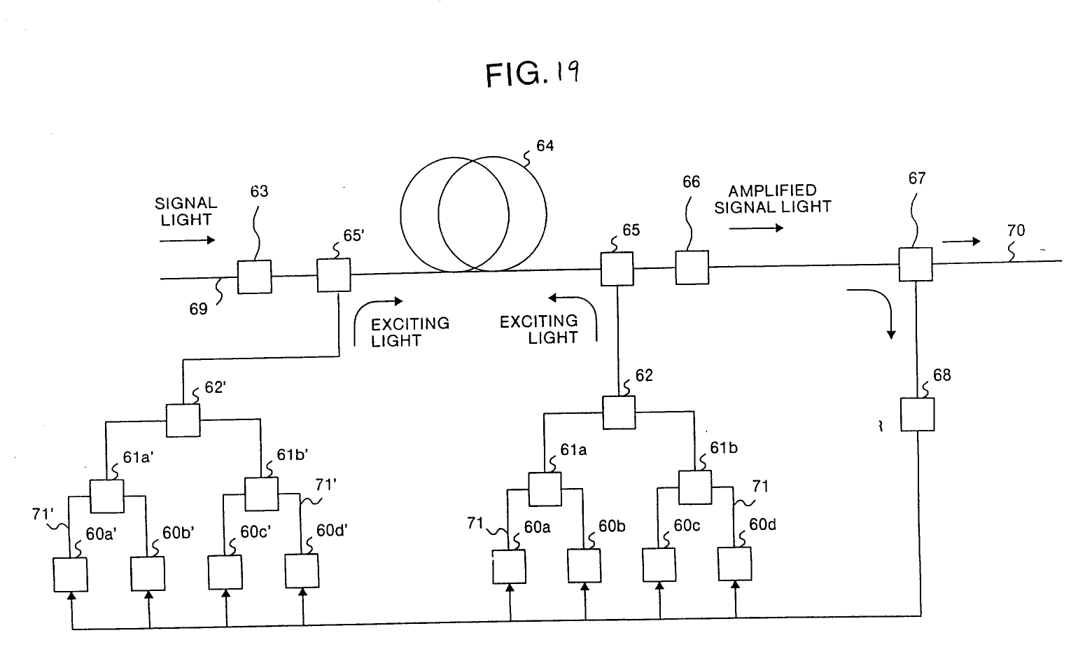

FIG. 17 is a block diagram illustrating a configuration of a Raman amplifier used in a WDM communication system in accordance with the present invention. In FIG. 17, semiconductor laser modules 60a through 60d are of the type described in the embodiment of FIG. 16. The laser modules 60a and 60b output laser beams having the same wavelength via polarization maintaining fiber 71 to polarization-multiplexing coupler. Similarly, laser beams outputted by each of the semiconductor laser modules 60c and 60d have the same wavelength, and they are polarization-multiplexed by the polarization-multiplexing coupler 61b. Each of the laser modules 60a through 60d outputs a laser beam having a plurality of oscillation longitudinal modes in accordance with the present invention to a respective polarization-multiplexing coupler 61a and 61b via a polarization maintaining fiber 71.

Polarization-multiplexing couplers 61a and 61b output polarization-multiplexed laser beams having different wavelengths to a WDM coupler 62. The WDM coupler 62 multiplexes the laser beams outputted from the polarization multiplexing couplers 61a and 61b, and outputs the multiplexed light beams as a pumping light beam to amplifying fiber 64 via WDM coupler 65. Signal light beams to be amplified are input to amplifying fiber 64 from signal light inputting fiber 69 via isolator 63. The amplified signal light beams are Raman-amplified by being multiplexed with the pumping light beams and input to a monitor light branching coupler 67 via the WDM coupler 65 and the polarization-independent isolator 66. The monitor light branching coupler 67 outputs a portion of the amplified signal light beams to a control circuit 68, and the remaining amplified signal light beams as an output laser beam to signal light outputting fiber 70.

The control circuit 68 controls a light-emitting state, for example, an optical intensity, of each of the semiconductor laser module 60a through 60d based on the portion of the amplified signal light beams input to the control circuit 68. This optical intensity of the Raman amplifier output is used along with the monitor current photodiode 56 of the laser module in FIG. 16 to control the output of the semiconductor lasers of each module. Thus, control circuit 68 performs feedback control of a gain band of the Raman amplification such that the gain band will be flat over wavelength.

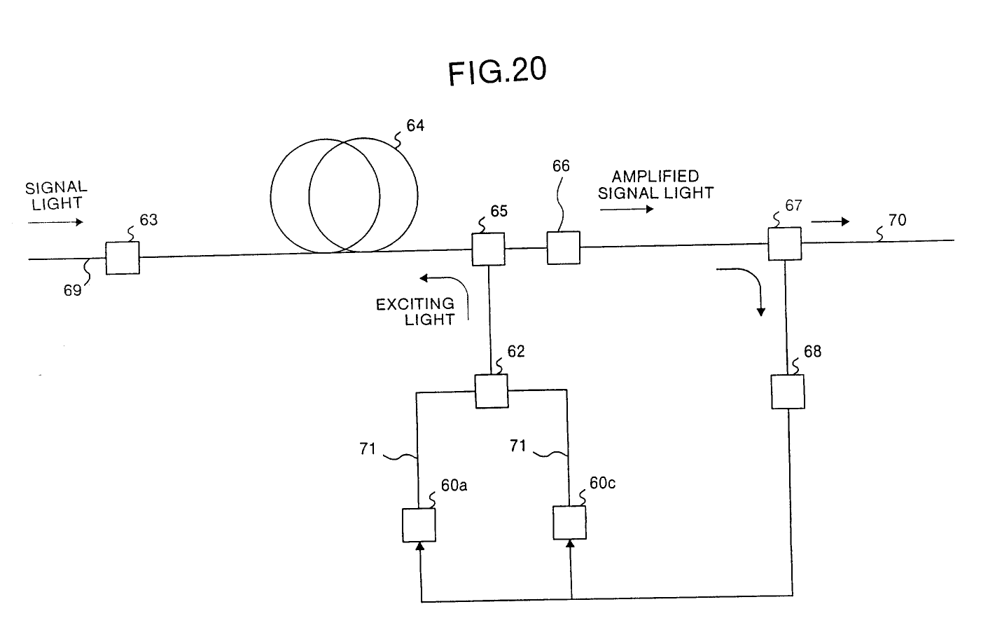

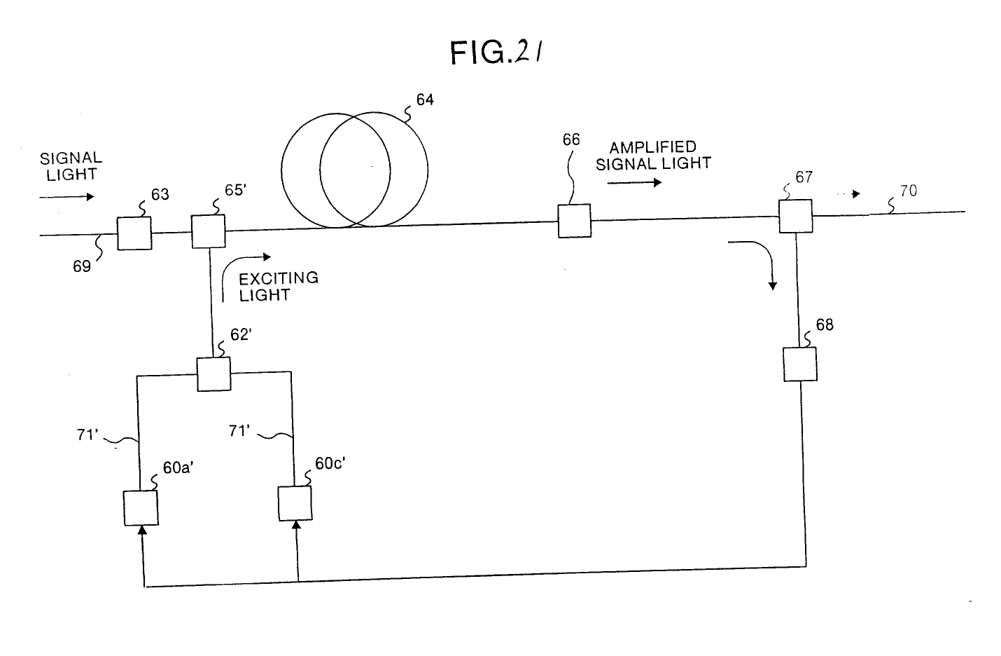

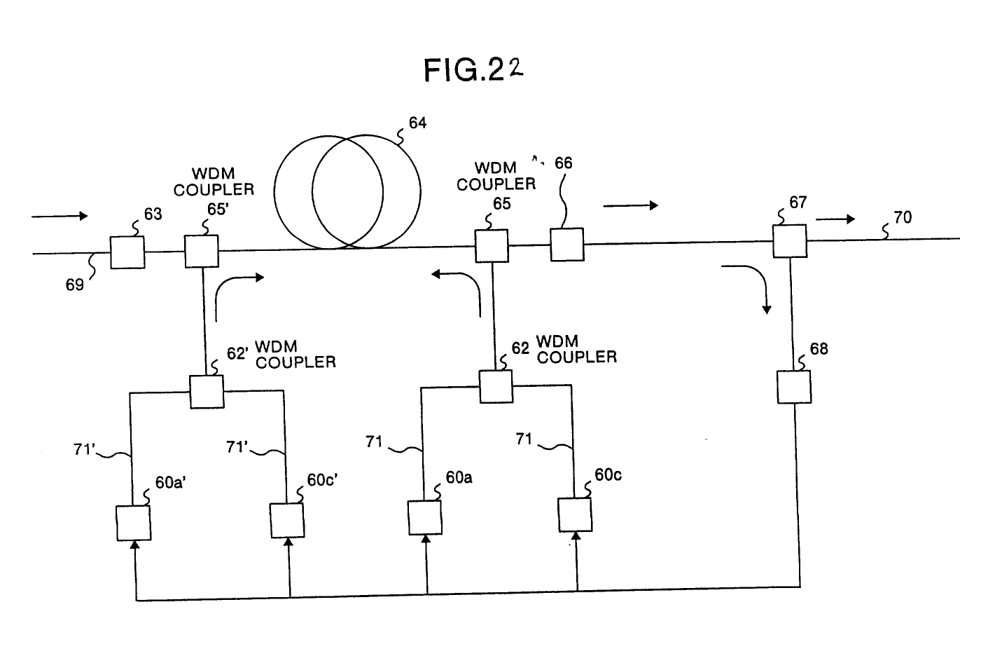

Although the Raman amplifier illustrated in FIG. 17 is the backward pumping method, it is to be understood that the semiconductor laser device, module and Raman amplifier of the present invention may be used with a forward pumping method as shown in FIG. 18, or the bi-directional pumping method as shown in FIG. 19. Moreover, the Raman amplifier can be constructed by wavelength-multiplexing of a plurality of pumping light sources which are not polarization-multiplexed. That is, the semiconductor laser module of the present invention can be used in a Raman amplifier where the polarization-multiplexing of pumping light is not performed. FIG. 20 is a block diagram illustrating a configuration of a Raman amplifier in which polarization dependency is canceled by depolarizing a pumping light beam output from a single semiconductor laser device using polarization maintaining fibers as a depolarizer, in accordance with an embodiment of the present invention. As seen in this figure, laser modules 60A and 60C are directly connected to WDM coupler 62 via a polarization maintaining fiber 71. In this configuration, the angle of the polarization axis of the polarization maintaining fiber against the emitted light from semiconductor laser device is approximately 45 degrees. Finally, it is to be understood that the semiconductor laser device, module and Raman amplifier of the present invention shown in FIG. 19 may be used with a forward pumping method as shown in FIG. 21, or the bi-directional pumping method as shown in FIG. 22.

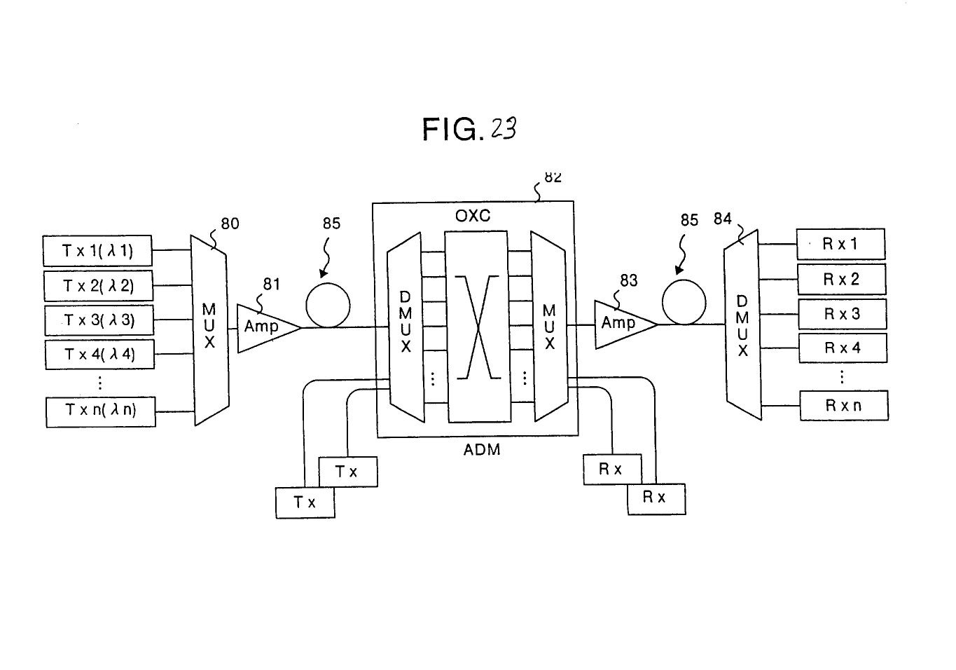

The Raman amplifier illustrated in FIGS. 17-22 can be applied to the WDM communication system as described above. FIG. 23 is a block diagram illustrating a general configuration of the WDM communication system to which the Raman amplifier shown in any of FIGS. 17-22 is applied.

In FIG. 22, optical signals of wavelengths λ₁ through λₙ are forwarded from a plurality of transmitter Tx₁ through Txₙ to multiplexing coupler 80 where they are wavelength-multiplexed and output to optical fiber 85 line for transmission to a remote communications unit. On a transmission route of the optical fiber 85, a plurality of Raman amplifiers 81 and 83 corresponding to the Raman amplifier illustrated in FIG. 21 or FIG. 22 are disposed amplifying an attenuated optical signal. A signal transmitted on the optical fiber 85 is divided by an optical demultiplexer 84 into optical signals of a plurality of wavelengths λ₁ through λₙ, which are received by a plurality of receivers Rx₁ through Rxₙ. Further, an ADM (Add/Drop Multiplexer) may be inserted on the optical fiber 85 for inserting and removing an optical signal of an arbitrary wavelength.

Obviously, numerous modifications and variations of the present invention are possible in light of the above teachings. It is therefore to be understood that within the scope of the appended claims, the invention may be practiced otherwise than as specifically described herein. For example, the present invention has been described as a pumping light source for the Raman amplification, it is evident that the configuration is not limited to this usage and may be used as an EDFA pumping light source of the oscillation wavelength of 980 nm and 1480 nm.

What is claimed is:

1. A semiconductor laser device comprising:
an active layer configured to radiate light;
a light reflecting facet positioned on a first side of said active layer;
a light emitting facet positioned on a second side of said active layer thereby forming a resonator between said light reflecting facet and said light emitting facet; and
a diffraction grating positioned within said resonator along the length of said active layer, wherein said laser is configured to output a multiple mode laser beam and at least one of said light reflecting and light emitting facets is horizontally offset by an offset angle with respect to a plane perpendicular to the light emitting direction of the laser device.

2. The semiconductor laser device of claim 1, wherein said at least one of said light reflecting and light emitting facets comprises a light emitting facet horizontally offset by an offset angle with respect to a plane perpendicular to the light emitting direction.

3. The semiconductor laser device of claim 2, wherein said offset angle of the light emitting facet is 2° or more.

4. The semiconductor laser device of claim 3, wherein said offset angle of the light emitting facet is approximately 7°.

5. The semiconductor laser device of claim 2, wherein said light emitting facet comprises a reflectance coating that provides a reflectivity of approximately 10%, approximately 5%, approximately 1%, approximately 0.5%, or approximately 0.1%.

6. The semiconductor laser device of claim 5, wherein said offset angle is a value necessary to provide an effective reflectivity of the light emitting facet at a value less than 1%.

7. The semiconductor laser device of claim 5, wherein said offset angle is a value necessary to provide an effective reflectivity of the light emitting facet at a value less than 0.1%.

8. The semiconductor laser device of claim 2, wherein said light reflecting facet forms a plane substantially perpendicular to a plane perpendicular to the light emitting direction of the laser device.

9. The semiconductor laser device of claim 2, wherein said diffraction grating is a partial diffraction grating positioned along a portion of said active layer in the vicinity of said light emitting facet.

10. The semiconductor device of claim 9, wherein a length of said partial diffraction grating and a length of said resonator are set to meet the inequality:
Lg×(1300/L)≦300,
where Lg is the predetermined length of the partial diffraction grating in μm, and
L is the length of the resonator in μm.

11. The semiconductor device of claim 9, wherein a length and a coupling coefficient of said partial diffraction grating are set to meet the inequality:
κ·Lg≦0.3,
where κ is the coupling coefficient of the diffraction grating, and
Lg is the length of the diffraction grating in μm.

12. The semiconductor laser device of claim 1, wherein said at least one of said light reflecting and light emitting facets comprises a light reflecting facet horizontally offset by an offset angle with respect to a plane perpendicular to the light emitting direction.

13. The semiconductor laser device of claim 12, wherein said offset angle of the light reflecting facet is 2° or more.

14. The semiconductor laser device of claim 13, wherein said offset angle of the light reflecting facet is approximately 7°.

15. The semiconductor laser device of claim 12, wherein said light reflecting facet comprises a reflectance coating.

16. The semiconductor laser device of claim 15, wherein said offset angle is a value necessary to provide an effective reflectivity of the light reflecting facet at a value less than 1%.

17. The semiconductor laser device of claim 15, wherein said offset angle is a value necessary to provide an effective reflectivity of the light reflecting facet at a value less than 0.1%.

18. The semiconductor laser device of claim 12, wherein said light emitting facet forms a plane substantially perpendicular to the light emitting direction of the laser device.

19. The semiconductor laser device of claim 12, wherein said diffraction grating is a partial diffraction grating positioned along a portion of said active layer in the vicinity of said light reflecting facet.

20. The semiconductor device of claim 19, wherein a length of said partial diffraction grating and a length of said resonator are set to meet the inequality:
Lg≦½L,
where Lg is the predetermined length of the partial diffraction grating in μm, and
L is the length of the resonator in μm.

21. The semiconductor device of claim 19, wherein a length and a coupling coefficient of said partial diffraction grating are set to meet the inequality:
κ·Lg≧1,
where κ is the coupling coefficient of the diffraction grating, and
Lg is the length of the diffraction grating.

22. The semiconductor laser device of claim 1, wherein said at least one of said light reflecting and light emitting facets comprises:
a light reflecting facet horizontally offset by an offset angle with respect to a plane perpendicular to the light emitting direction; and
a light reflecting facet horizontally offset by an offset angle with respect to the light emitting direction.

23. The semiconductor laser device of claim 1, further comprising a light waveguide layer in which the diffraction grating is formed.

24. A method of providing a multiple mode laser output from a semiconductor laser device comprising:
radiating light from an active layer of the laser device;
providing a light reflecting facet positioned on a first side of said active layer and a light emitting facet positioned on a second side of said active layer thereby forming a resonator between said light reflecting facet and said light emitting facet;
providing a diffraction grating positioned within said resonator along a portion of the length of said active layer and configured to provide said multiple mode laser output; and
suppressing Fabry-Perot oscillations by horizontally offsetting at least one of said light reflecting and light emitting facets by an offset angle with respect to a plane perpendicular to the light emitting direction of the laser device.

25. The method of claim 24, wherein said suppressing Fabry-Perot oscillations comprises horizontally offsetting said light emitting facet by an offset angle with respect to a plane perpendicular to the light emitting direction.

26. The method of claim 25, further comprising coating the light emitting facet with a reflective coating that provides a reflectivity of approximately 10%, approximately 5%, approximately 1%, approximately 0.5%, or approximately 0.1%.

27. The semiconductor laser device of claim 25, wherein said offset angle is a value necessary to provide an effective reflectivity of the light reflecting facet at a value less than 1%.

28. The semiconductor laser device of claim 25, wherein said offset angle is a value necessary to provide an effective reflectivity of the light reflecting facet at a value less than 0.1%.

29. The method of claim 24, wherein said suppressing Fabry-Perot oscillations comprises horizontally offsetting said light reflecting facet by an offset angle with respect to a plane perpendicular to the light emitting direction.

30. The method of claim 29, further comprising coating the light reflecting facet with a reflective coating that provides a reflectivity of approximately 10%, approximately 5%, approximately 1%, approximately 0.5%, or approximately 0.1%.

31. The method of claim 29, wherein said horizontally offsetting comprises horizontally offsetting said light reflecting facet such that an effective reflectivity of the light reflecting facet is less than 0.1%.

32. The method of claim 29, wherein said horizontally offsetting comprises horizontally offsetting said light reflecting facet such that an effective reflectivity of the light reflecting facet is less than 1%.

33. The method of claim 24, wherein said suppressing Fabry-Perot oscillations comprises:
horizontally offsetting said light emitting facet by an offset angle with respect to a plane perpendicular to the light emitting direction; and
horizontally offsetting said light reflecting facet by an offset angle with respect to a plane perpendicular to the light emitting direction.

34. The method of claim 24, further comprising forming a light waveguide layer in which the diffraction grating is formed.

35. The method of claim 24, wherein said horizontally offsetting comprises horizontally offsetting at least one of said light emitting and light reflecting facets by an offset angle that is determined based on a desired effective reflectivity and a far field pattern (FFP) angle.

36. The method of claim 35, further comprising horizontally offsetting at least one of said light emitting and light reflecting facets by an offset angle of about 2.1° to about 3° to achieve the desired effective reflectivity of 1% for the FFP range of about 13°-18°.

37. The method of claim 35, further comprising horizontally offsetting at least one of said light emitting and light reflecting facets by an offset angle of about 2.4° to about 3.3° to achieve the desired effective reflectivity of 1% for the FFP range of about 13°-18°.

38. The method of claim 35, further comprising horizontally offsetting at least one of said light emitting and light reflecting facets by an offset angle of about 3.3° to about 3.8° to achieve the desired effective reflectivity of 1% for the FFP range of about 13°-18°.

39. A semiconductor device comprising:
means for radiating light from an active layer of said device;
means for oscillating said radiated light within the cavity and emitting a portion of said radiated light from the laser device as a multiple mode light output beam;
means for selecting said portion of said radiated light to be emitted by said semiconductor laser device; and means for suppressing Fabry-Perot oscillations of said means for oscillating.

40. A semiconductor laser module comprising:
a semiconductor laser device comprising:
an active layer configured to radiate light,
a light reflecting facet positioned on a first side of said active layer,
a light emitting facet positioned on a second side of said active layer thereby forming a resonator between said light reflecting facet and said light emitting facet, and
a diffraction grating positioned within said resonator along the length of said active layer, wherein said laser device is configured to output a multiple mode laser beam and at least one of said light reflecting and light emitting facets is horizontally offset by an offset angle with respect to a plane perpendicular to the light emitting direction of the laser device; and
a wave guide device for guiding said laser beam away from the semiconductor laser device.

41. An optical fiber amplifier comprising:
a semiconductor laser device comprising:
an active layer configured to radiate light,
a light reflecting facet positioned on a first side of said active layer,
a light emitting facet positioned on a second side of said active layer thereby forming a resonator between said light reflecting facet and said light emitting facet, and
a diffraction grating positioned within said resonator along the length of said active layer, wherein said laser device is configured to output a multiple mode laser beam and at least one of said light reflecting and light emitting facets is horizontally offset by an offset angle with respect to a plane perpendicular to the light emitting direction of the laser device; and
an amplifying fiber coupled to said semiconductor laser device and configured to amplify a signal by using said light beam as an excitation light.

42. A wavelength division multiplexing system comprising:
a transmission device configured to provide a plurality of optical signals having different wavelengths;
an optical fiber amplifier coupled to said transmission device and including a semiconductor laser device comprising:
an active layer configured to radiate light,
a light reflecting facet positioned on a first side of said active layer,
a light emitting facet positioned on a second side of said active layer thereby forming a resonator between said light reflecting facet and said light emitting facet, and
a diffraction grating positioned within said resonator along the length of said active layer, wherein said laser device is configured to output a multiple mode laser beam and at least one of said light reflecting and light emitting facets is horizontally offset by an offset angle with respect to a plane perpendicular to the light emitting direction of the laser device; and
a receiving device coupled to said optical fiber amplifier and configured to receive said plurality of optical signals having different wavelengths.

43. A Raman amplifier comprising:
a semiconductor laser device comprising:
an active layer configured to radiate light,
a light reflecting facet positioned on a first side of said active layer,
a light emitting facet positioned on a second side of said active layer thereby forming a resonator between said light reflecting facet and said light emitting facet, and
a diffraction grating positioned within said resonator along the length of said active layer, wherein said laser device is configured to output a multiple mode laser beam at least one of said light reflecting and light emitting facets is horizontally offset by an offset angle with respect to a plane perpendicular to the light emitting direction of the laser device; and
a fiber coupled to said semiconductor laser device and configured to carry a signal that is amplified based on said light beam being applied to said fiber.

44. The Raman amplifier of claim 43, wherein said semiconductor laser device is coupled to said fiber at an input side of said fiber such that said light beam is applied in a forward pumping method.

45. The Raman amplifier of claim 43, wherein said semiconductor laser device is coupled to said fiber at an output side of said fiber such that said light beam is applied in a backward pumping method.

46. The Raman amplifier of claim 43, wherein said semiconductor laser device is coupled to said fiber at both an input and output side of said fiber such that said light beam is applied in both a forward and backward pumping method.
